(19) United States
(12) Patent Application Publication
(10) Pub. No.: US 2025/0060417 A1
(43) Pub. Date: Feb. 20, 2025

(54) BATTERY STATE ANALYSIS SYSTEM, BATTERY STATE ANALYSIS METHOD, AND NON-TRANSITORY COMPUTER-READABLE RECORDING MEDIUM

(71) Applicant: Panasonic Intellectual Property Management Co., Ltd., Osaka (JP)

(72) Inventor: Shigeru MATSUDA, Osaka (JP)

(21) Appl. No.: 18/721,145

(22) PCT Filed: Dec. 7, 2022
(86) PCT No.: PCT/JP2022/045069

§ 371 Date: Jun. 17, 2024

(30) Foreign Application Priority Data
Dec. 23, 2021 (JP) 2021-209746

(51) Int. Cl. G01R 31/389; G01R 31/36; G01R 31/3842; G01R 31/396

(52) U.S. Cl. CPC G01R 31/389; G01R 31/3648; G01R 31/3842; G01R 31/396

(57) ABSTRACT

An ohmic resistance estimation unit estimates an ohmic resistance value of each cell or each parallel cell block, based on the voltage data and the current data for each cell or each parallel cell block of a battery pack. A statistical calculation unit statistically processes the ohmic resistance value of each cell or each parallel cell block and calculates a representative value of the ohmic resistance value of a single cell or a single parallel cell block of a particular battery pack or of a plurality of battery packs of the same type. A correction value generation unit generates an external resistance correction value for correcting deviation of an external resistance of each cell or each parallel cell block, based on a difference between the ohmic resistance value of each cell or each parallel cell block and the representative value of the ohmic resistance value.

### CROSS-REFERENCE TO RELATED APPLICATIONS

This application is based upon and claims the benefit of priority from the prior Japanese Patent Application No. 2021-209746, filed on Dec. 23, 2021, and the International Patent Application No. PCT/JP2022/045069, filed on Dec. 7, 2022, the entire content of each of which is incorporated herein by reference.

### BACKGROUND

### Field of the Invention

The present disclosure relates to a battery state analysis system, a battery state analysis method, and a battery state analysis program for estimating an external state of a battery.

### Description of the Related Art

In a battery pack including a plurality of single cells or parallel cell blocks (comprised of a plurality of cells connected in parallel) connected in series, the voltage of a particular single cell or parallel cell block may be deviated from the voltage of other single cells or parallel cell blocks during charging and discharging. According to our analysis, deviation is estimated to be caused by a mechanical factor external to the battery (for example, external resistance such as wiring resistance and contact resistance) because deviation tends to occur in a single cell or a parallel cell block at the same position in battery packs of the same type. This mechanical factor external to the battery leads to an estimation error incurred when estimating an internal state of the battery (e.g., internal resistance, etc.).

With regard to a method of estimating an internal state of a battery, there is proposed a method in which a parameter ratio of each block is calculated by dividing a parameter (e.g., internal resistance) of each parallel battery block by an average value of the entire blocks and determining degradation according to a difference between a moving-average value of the parameter ratio of each block and the current parameter ratio (see, for example, Patent Literature 1).

There is also proposed a method in which the ohmic resistance Ro (Ro=Ra+Rb, Rb=A*exp(B/T(t)) is defined according to a non-temperature dependent resistance Ra and a temperature dependent resistance Rb, the ohmic resistance Ro given by ΔV/ΔI is regarded as a true value, and the internal resistance is estimated by sequentially identifying the parameters Ra, A, and B in the expression (see, for example, Patent Literature 2).
Patent Literature 1: JP2021-173551
Patent Literature 2: JP2021-56095

None of the above methods takes into account the influence of a factor external to the battery, and so an error may occur when an internal state is estimated.

### SUMMARY OF THE INVENTION

The present disclosure addresses the issue described above, and a purpose thereof is to provide a technology that contributes to highly accurate estimation of an internal state of a battery.

A battery state analysis system according to an embodiment of the present disclosure includes: a data acquisition unit that acquires voltage data and current data for each cell of a battery pack in which a plurality of cells are connected in series or for each parallel cell block of battery pack in which parallel cell blocks, each comprised of a plurality of cells connected in parallel, are connected in series; an ohmic resistance estimation unit that estimates an ohmic resistance value of each cell or each parallel cell block, based on the voltage data and the current data for each cell or each parallel cell block; a statistical calculation unit that statistically processes the ohmic resistance value of each cell or each parallel cell block and calculates a representative value of the ohmic resistance value of a single cell or a single parallel cell block of a particular battery pack or of a plurality of battery packs of the same type; and a correction value generation unit that generates an external resistance correction value for correcting deviation of an external resistance of each cell or each parallel cell block, based on a difference between the ohmic resistance value of each cell or each parallel cell block and the representative value of the ohmic resistance value.

Optional combinations of the aforementioned constituting elements, and implementations of the present disclosure in the form of apparatuses, systems, methods, and computer programs are also useful as embodiments of the present disclosure.

Embodiments will now be described, by way of example only, with reference to the accompanying drawings which are meant to be exemplary, not limiting, and wherein like elements are numbered alike in several Figures, in which:

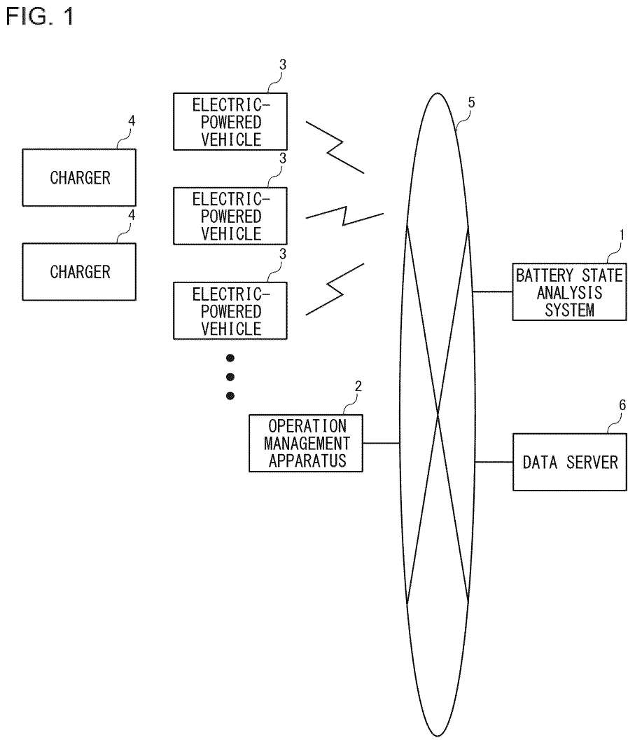

FIG. 1 is a diagram for illustrating a battery state analysis system according to the embodiment.

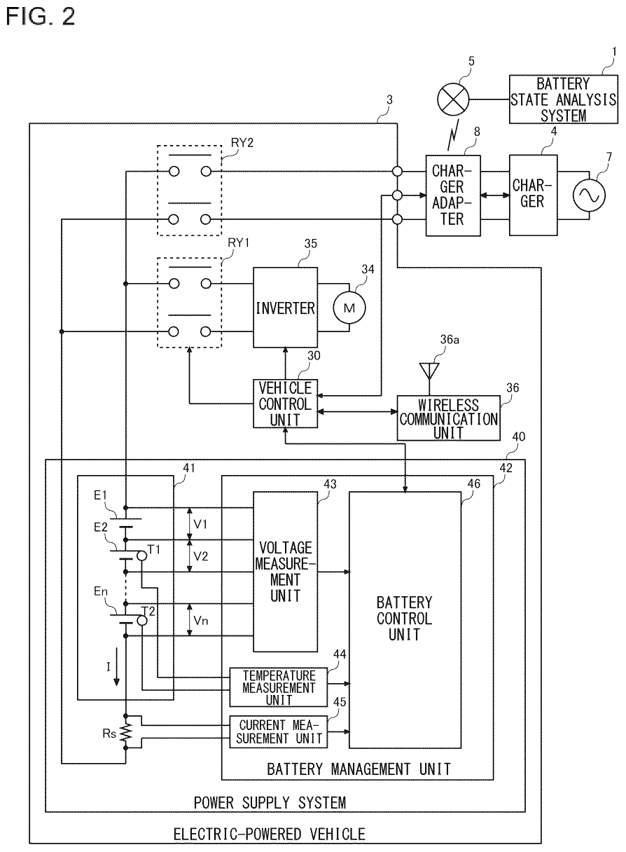

FIG. 2 is a diagram for illustrating a detailed configuration of a power supply system mounted on the electric-powered vehicle.

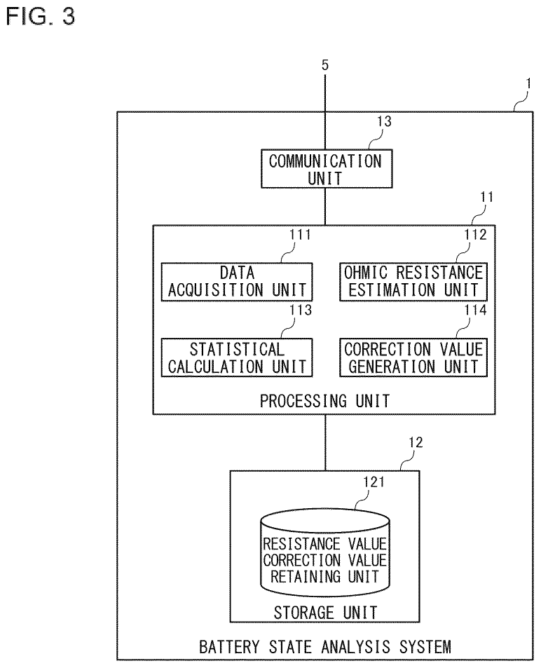

FIG. 3 is a diagram showing an exemplary configuration of the battery state analysis system according to the embodiment.

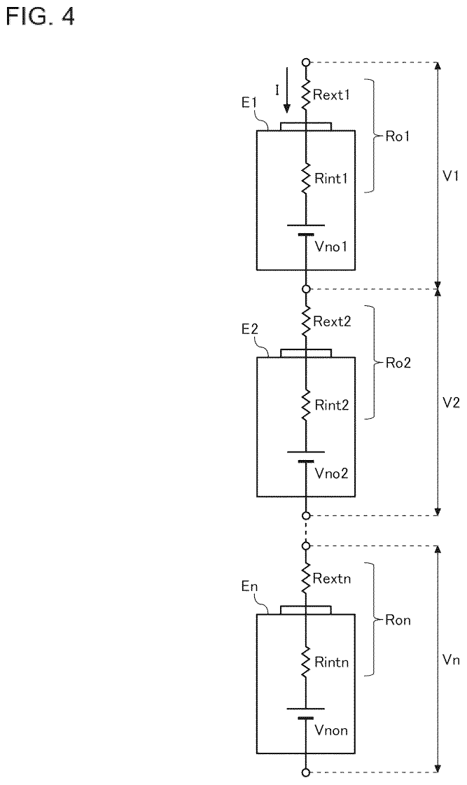

FIG. 4 is an equivalent circuit diagram for illustrating ohmic resistance.

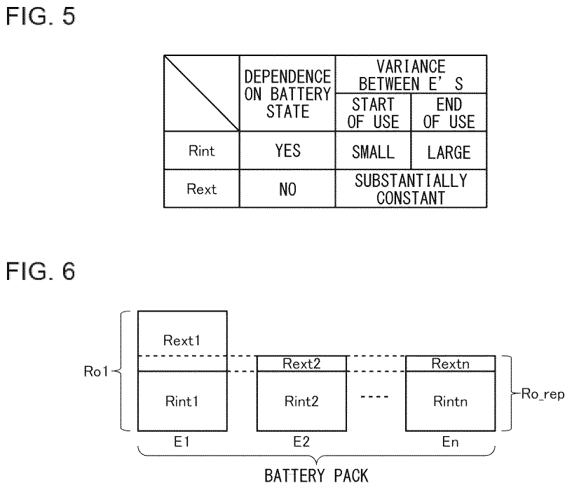

FIG. 5 is a table that summarizes the properties of the internal resistance and the external resistance contained in the ohmic resistance.

FIG. 6 is a diagram illustrating a specific example of breakdown of ohmic resistance components of the plurality of cells contained in the battery pack at the beginning of use.

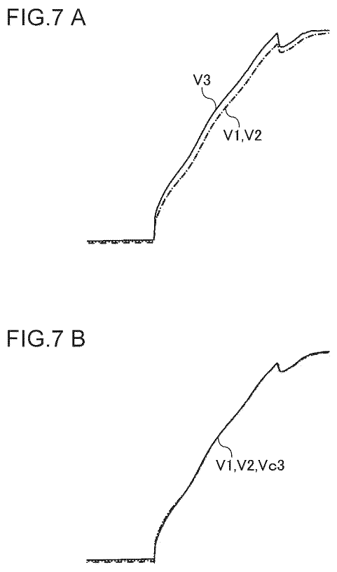

FIGS. 7A-7B are diagrams illustrating specific examples of the voltage waveform at the time of CC-CV charging of three cells connected in series.

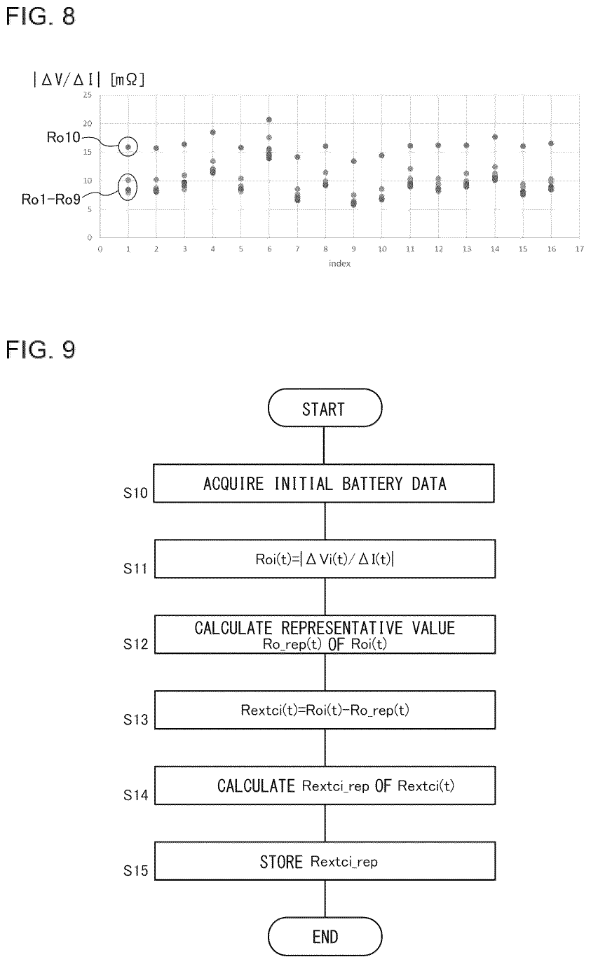

FIG. 8 is a diagram showing an exemplary transition of the estimate internal resistance value of ten cells connected in series.

FIG. 9 is a flowchart showing the flow of an external resistance correction value generation process performed by the battery state analysis system according to the embodiment.

### DETAILED DESCRIPTION OF THE INVENTION

The invention will now be described by reference to the preferred embodiments. This does not intend to limit the scope of the present invention, but to exemplify the invention.

FIG. 1 is a diagram for illustrating a battery state analysis system 1 according to the embodiment. The battery state analysis system 1 according to the embodiment is a system used by at least one delivery company. The battery state analysis system 1 may, for example, be built on an in-house server provided in an in-house facility of a service provider that provides a battery state analysis service of a battery pack 41 (see FIG. 2) mounted on an electric-powered vehicle 3 or in a data center. Alternatively, the battery state analysis system 1 may be built on a cloud server that is used based on a cloud service. Alternatively, the battery state analysis system 1 may be built on a plurality of servers distributed at a plurality of sites (data centers, in-house facilities). The plurality of servers may be any of a combination of a plurality of in-house servers, a combination of a plurality of cloud servers, or a combination of an in-house server and a cloud server.

The network 5 is a general term for communication channels such as the Internet, leased lines, and VPN (Virtual Private Network), and the communication medium and the protocol thereof do not matter. For example, a mobile phone network (cellular network), a wireless LAN, a wired LAN, an optical fiber network, an ADSL network, a CATV network, and the like can be used as the communication medium. For example, TCP (Transmission Control Protocol)/IP (Internet Protocol), UDP (User Datagram Protocol)/IP, Ethernet (registered trademark) and the like can be used as the communication protocol.

The delivery company owns a plurality of electric-powered vehicles 3 and a plurality of chargers 4 and uses the plurality of electric-powered vehicles 3 for delivery business. It should be noted that the electric-powered vehicle 3 can be charged from a charger other than the charger 4 provided at a delivery base. The delivery company owns delivery base for parking the electric-powered vehicle 3. The operation management terminal apparatus 2 is provided in the delivery base. For example, the operation management terminal apparatus 2 is comprised of a PC. The operation management terminal apparatus 2 is used to manage a plurality of electric-powered vehicle 3 belonging to the delivery base.

The operation management terminal apparatus 2 can access the battery state analysis system 1 via the network 5 and use the service of analyzing the state of the battery pack mounted on the electric-powered vehicle 3. In a state where the electric-powered vehicle 3 is parked at the delivery base, the vehicle control unit 30 (see FIG. 2) of the electric-powered vehicle 3 and the operation management terminal apparatus 2 can exchange data via the network 5 (for example, wireless LAN), a CAN cable, or the like. The vehicle control unit 30 and the operation management terminal apparatus 2 may be configured to exchange data via the network 5 even while the electric-powered vehicle 3 is traveling.

The data server 6 acquires and stores traveling data from the operation management terminal apparatus 2 or the electric-powered vehicle 3. The data server 6 may be an in-house server provided in an in-house facility of a delivery company or a battery state analysis service provider or in a data center. The data server 6 may be a cloud server used by the delivery company or the battery state analysis service provider. Further, each delivery company and battery state analysis service provider may have the data server 6.

FIG. 2 is a diagram for illustrating a detailed configuration of a power supply system 40 mounted on the electric-powered vehicle 3. The power supply system 40 is connected to a motor 34 via a first relay RY1 and an inverter 35. The inverter 35 converts a DC power supplied from the power supply system 40 into an AC power and supplies it to the motor 34 during power running. During regeneration, the inverter 35 converts the AC power supplied from the motor 34 into a DC power and supplies it to the power supply system 40. The motor 34 is a three-phase AC motor and rotates according to the AC power supplied from the inverter 35 during power running. During regeneration, the motor 34 converts the rotational energy caused by deceleration into an AC power and supplies it to the inverter 35.

The vehicle control unit 30 is a vehicle ECU (Electronic Control Unit) that controls the entire electric-powered vehicle 3 and may be, for example, comprised of an integrated VCM (Vehicle Control Module). A wireless communication unit 36 has a modem and performs a wireless signal process for wireless connection to the network 5 via an antenna 36a. Examples of a wireless communication network to which the electric-powered vehicle 3 can be wirelessly connected include a mobile phone network (cellular network), a wireless LAN, V2I (Vehicle-to-Infrastructure), V2V (Vehicle-to-Vehicle), ETC system (Electronic Toll Collection System), and DSRC (Dedicated Short Range Communications).

The first relay RY1 is a contactor inserted between the wirings connecting the power supply system 40 and the inverter 35. The vehicle control unit 30 controls the first relay RY1 to be on (closed state) while the vehicle is running to electrically connect the power supply system 40 and the power system of the electric-powered vehicle 3. While the vehicle is not running, the vehicle control unit 30 controls the first relay RY1 to be off (open state) in principle and electrically cuts off the power supply system 40 and the power system of the electric-powered vehicle 3 from each other. Instead of a relay, a different type of switch such as a semiconductor switch may be used.

The electric-powered vehicle 3 is adapted to charge a battery pack 41 in the power supply system 40 from outside by being connected to the charger 4. In this embodiment, the electric-powered vehicle 3 is connected to the charger 4 via a charger adapter 8. The charger adapter 8 is mounted on, for example, the end of the terminal of the charger 4. When the charger adapter 8 is mounted on the charger 4, the control unit in the charger adapter 8 establishes a communication channel with the control unit in the charger 4.

The charger adapter 8 is preferably comprised of a small housing. In that case, the driver of the electric-powered vehicle 3 can easily carry the charger adapter 8 and can use the charger adapter 8 by mounting it on a charger 4 other than the charger 4 provided at the delivery base. For example, the driver can use the charger adapter 8 by mounting it on a charger 4 other than the charger 4 provided at the delivery base such as the charger 4 provided in a public facility, a commercial facility, a gas station, a car dealer, or a highway service area.

When the charger adapter 8 mounted on the charger 4 and the electric-powered vehicle 3 are connected by a charging cable, the battery pack 41 in the electric-powered vehicle 3 can be charged from the charger 4. The charger adapter 8 causes the power supplied from the charger 4 to pass through to the electric-powered vehicle 3. The charger adapter 8 has a wireless communication function and can exchange data with the battery state analysis system 1 via the network 5. The charger adapter 8 functions as a gateway that relays communication between the electric-powered vehicle 3 and the charger 4, between the electric-powered vehicle 3 and the battery state analysis system 1, and between the charger 4 and the battery state analysis system 1.

The charger 4 is connected to a commercial power system 7 and charges the battery pack 41 in the electric-powered vehicle 3. In the electric-powered vehicle 3, a second relay RY2 is inserted between the wirings connecting the power supply system 40 and the charger 4. Instead of a relay, a different type of switch such as a semiconductor switch may be used. A battery management unit 42 controls the second relay RY2 to be on via the vehicle control unit 30 or directly before charging is started and controls the second relay RY2 to be off after charging is completed.

In general, a battery is charged with AC in the case of normal charging and is charged with DC in the case of fast charging. In the case of charging the battery with AC (for example, single-phase 100/200 V), the AC power is converted into a DC power by an AC/DC converter (not shown) inserted between the second relay RY2 and the battery pack 41. In the case of charging the battery with DC, the charger 4 generates the DC power by rectifying the AC power supplied from the commercial power system 7 in full wave rectification and smoothing the power with a filter.

Examples of fast charging standards that can be used include CHAdeMO (registered trademark), ChaoJi, GB/T, Combo (Combined Charging System). CHAdeMO2.0 stipulates that the maximum output (specification) is 1000VX400 A=400 kW. CHAdeMO3.0 stipulates that the maximum output (specification) is 1500VX600 A=900 kW. ChaoJi stipulates that the maximum output (specification) is 1500VX600 A=900 kW. GB/T stipulates that the maximum output (specification) is 750VX250 A=185 kW. Combo stipulates that the maximum output (specification) is 900VX400 A=350 kW. CHAdeMO, ChaoJi, and GB/T use CAN (Controller Area Network) as the communication method. Combo uses PLC (Power Line Communication) as the communication method.

In addition to power lines, communication lines are also included in the charging cable in which the CAN scheme is employed. When the electric-powered vehicle 3 and the charger adapter 8 are connected by the charging cable, the vehicle control unit 30 establishes a communication channel with the control unit in the charger adapter 8. In the charging cable in which the PLC scheme is employed, a communication signal is superimposed and transmitted on the power line.

The vehicle control unit 30 establishes a communication channel with the battery management unit 42 via a vehicle-mounted network (for example, CAN or LIN (Local Interconnect Network)). When the communication standard between the vehicle control unit 30 and the control unit in the charger adapter 8 and the communication standard between the vehicle control unit 30 and the battery management unit 42 are different, the vehicle control unit 30 performs a gateway function.

The power supply system 40 mounted on the electric-powered vehicle 3 includes the battery pack 41 and the battery management unit 42. The battery pack 41 includes a plurality of cells. FIG. 2 shows an exemplary configuration in which a plurality of cells (E1-En) are connected in series. The battery pack 41 may be configured such that a plurality of parallel cell blocks, each comprised of a plurality of cells connected in parallel, are connected in series. A lithium ion battery cell, a nickel hydride battery cell, a lead battery cell or the like can be used as the cell. Hereinafter, an example of using a lithium ion battery cell (nominal voltage: 3.6-3.7 V) is assumed in this specification. The number of cells E1-En or the parallel cell blocks connected in series is determined according to the drive voltage of the motor 34.

A shunt resistor Rs is connected in series with the plurality of cells E1-En or the plurality of parallel cell blocks. The shunt resistor Rs functions as a current-sensing element. A Hall element may be used instead of the shunt resistor Rs. A plurality of temperature sensors T1, T2 for detecting the temperature of the plurality of cells E1-En or the plurality of parallel cell blocks are provided in the battery pack 41. For example, a thermistor can be used as the temperature sensors T1, T2. For example, one temperature sensor may be provided for 6-8 cells or parallel cell blocks.

The battery management unit 42 includes a voltage measurement unit 43, a temperature measurement unit 44, a current measurement unit 45, and a battery control unit 46. The nodes of the plurality of cells E1-En or the plurality of parallel cell blocks connected in series and the voltage measurement unit 43 are connected by a plurality of voltage lines. The voltage measurement unit 43 measures the voltage of each cell E1-En or each parallel cell block by measuring the voltage between two adjacent voltage lines respectively. The voltage measurement unit 43 transmits the voltage of each cell E1-En or each parallel cell block thus measured to the battery control unit 46.

Since the voltage measurement unit 43 is at a higher voltage than the battery control unit 46, the voltage measurement unit 43 and the battery control unit 46 are connected by a communication line in an electrically insulated state. The voltage measurement unit 43 can be comprised of an ASIC (Application Specific Integrated Circuit) or a general-purpose analog front-end IC. The voltage measurement unit 43 includes a multiplexer and an A/D converter. The multiplexer successively outputs the voltage between two adjacent voltage lines to the A/D converter from top to bottom. The A/D converter converts the analog voltage input from the multiplexer into a digital value.

The temperature measurement unit 44 includes a voltage divider resistor and an A/D converter. The A/D converter converts a plurality of analog voltages divided by the plurality of temperature sensors T1, T2 and the plurality of voltage divider resistors into digital values successively and outputs them to the battery control unit 46. The battery control unit 46 measures the temperature at a plurality of observation points in the battery pack 41.

The current measurement unit 45 includes a differential amplifier and an A/D converter. The differential amplifier amplifies the voltage across the shunt resistor Rs and outputs the amplified voltage to the A/D converter. The A/D converter converts the analog voltage input from the differential amplifier into a digital value and outputs it to the battery control unit 46. The battery control unit 46 measures a current I flowing through the plurality of cells E1-En or the plurality of parallel cell blocks based on the digital value.

In the case an A/D converter is mounted in the battery control unit 46 and an analog input port is provided in the battery control unit 46, the temperature measurement unit 44 and the current measurement unit 45 may output an analog voltage to the battery control unit 46, and the A/D converter in the battery control unit 46 may convert the analog voltage into a digital value.

The battery control unit 46 manages the state of the plurality of cells E1-En or the plurality of parallel cell blocks based on the voltage, temperature, and current of the plurality of cells E1-En or the plurality of parallel cell blocks measured by the voltage measurement unit 43, the temperature measurement unit 44, and the current measurement unit 45. When an overvoltage, undervoltage, overcurrent, or temperature abnormality occurs in at least one of the plurality of cells E1-En or the plurality of parallel cell blocks, the battery control unit 46 turns off the second relay RY2 or the protection relay (not shown) in the battery pack 41 to protect the cell or the parallel cell block.

The battery control unit 46 can be comprised of a microcontroller and a non-volatile memory (e.g., EEPROM (Electrically Erasable Programmable Read-Only Memory), flash memory). The battery control unit 46 estimates the SOC of each of the plurality of cells E1-En or the plurality of parallel cell blocks.

The battery control unit 46 estimates SOC by combining the OCV (Open Circuit Voltage) method and the current integration method. The OCV method is a method of estimating SOC based on the OCV of each cell measured by the voltage measurement unit 43 and the SOC-OCV curve of the cell. The SOC-OCV curve of the cell is created in advance based on a characteristic test by the battery manufacturer and is registered in the internal memory of the microcontroller at the time of shipment.

The current accumulation method is a method of estimating SOC based on the OCV at the start of charging or discharging of each cell and the integrated value of the current measured by the current measurement unit 45. In the current accumulation method, the measurement error of the current measurement unit 45 accumulates as the charging/discharging time increases. On the other hand, the OCV method is affected by the measurement error of the voltage measurement unit 43 and the error caused by the polarization voltage. It is therefore preferable to use a weighted average of the SOC estimated by the current accumulation method and the SOC estimated by the OCV method.

The battery control unit 46 periodically (for example, every 10 seconds) samples battery data including voltage, current, temperature, and SOC of each cell E1-En or each parallel cell block and transmits the data to the vehicle control unit 30 via the vehicle-mounted network. The vehicle control unit 30 can transmit battery data to the data server 6 in real time using the wireless communication unit 36 while the electric-powered vehicle 3 is running.

The vehicle control unit 30 may store the battery data for the electric-powered vehicle 3 in the internal memory and collectively transmit the battery data stored in the memory at a predetermined point of time. For example, the vehicle control unit 30 collectively transmits the battery data stored in the memory to the operation management terminal apparatus 2 at the end of the day's business. The operation management terminal apparatus 2 transmits the battery data for the plurality of electric-powered vehicles 3 to the data server 6 according to a predetermined timing schedule.

Alternatively, the vehicle control unit 30 may collectively transmit the battery data stored in the memory to the charger adapter 8 or the charger 4 having a network communication function via the charging cable when the battery is charged by the charger 4. The charger adapter 8 or the charger 4 having a network communication function transmits the received battery data to the data server 6. This example is useful for the electric-powered vehicle 3 not equipped with a wireless communication function.

FIG. 3 is a diagram showing an exemplary configuration of the battery state analysis system 1 according to the embodiment. The battery state analysis system 1 includes a processing unit 11, a storage unit 12, and a communication unit 13. The communication unit 13 is a communication interface (for example, NIC: Network Interface Card) for connecting to the network 5 by wire or wirelessly.

The processing unit 11 includes a data acquisition unit 111, an ohmic resistance estimation unit 112, a statistical calculation unit 113, and a correction value generation unit 114. The function of the processing unit 11 can be realized by cooperation between hardware resources and software resources or by hardware resources alone. Hardware resources such as CPU, ROM, RAM, GPU (Graphics Processing Unit), ASIC (Application Specific Integrated Circuit), FPGA (Field Programmable Gate Array), and other LSIs can be used. Programs such as operating systems and applications can be used as software resources.

The storage unit 12 is inclusive of a non-volatile recording medium such as a HDD and an SSD and stores various data. The storage unit 12 includes a resistance correction value retaining unit 121. For each battery pack 41, the resistance correction value retaining unit 121 retains an external resistance correction value for correcting the deviation of the external resistance of each cell or each parallel cell block included in the battery pack 41.

The data acquisition unit 111 acquires battery data for a specific battery pack 41 mounted on the electric-powered vehicle 3 from the data server 6. The battery data includes voltage data and current data for each cell or each parallel cell block of the particular battery pack 41. The data acquisition unit 111 acquires voltage data and current data for each cell or each parallel cell block in a predetermined period (e.g., one month) from the start of use of the particular battery pack 41.

The ohmic resistance estimation unit 112 estimates the ohmic resistance value of each cell or each parallel cell block of the battery pack 41 based on the voltage data and current data for each cell or each parallel cell block of the battery pack 41. Ohmic resistance refers to a resistance component with linear current-voltage characteristics according to Ohm's law. Ohmic resistance is categorized into internal resistance of the battery (for example, electrolyte component, etc.) and external resistance (for example, wiring resistance, contact resistance, etc.).

FIG. 4 is an equivalent circuit diagram for illustrating ohmic resistance. In the example described below, an example in which the battery pack 41 includes a plurality of single cells connected in series is assumed. The following description also applies to an example in which the battery pack 41 includes a plurality of parallel cell blocks connected in series. In the example shown in FIG. 4, the measured current of the battery pack 41 is denoted by I, the measured voltages of the plurality of cells E1, E2, . . . , and En included in the battery pack 41 are denoted by V1, V2, . . . , and Vn, and the ohmic resistances of the plurality of cells E1, E2, . . . , and En are denoted by Ro1, Ro2, . . . , and Ron. Of the ohmic resistances Ro1, Ro2, . . . , and Ron, the resistance components outside the cells are denoted by Rext1, Rext2, . . . , and Rextn, and the resistance components inside the cells are denoted by Rint1, Rint2, . . . , and Rintn. The non-ohmic voltages obtained by removing ohmic loss (I*Ro) from the measured voltage are denoted by Vno1, Vno2, . . . , Vnon.

FIG. 5 is a table that summarizes the properties of the internal resistance Rint and the external resistance Rext contained in the ohmic resistance Ro. The internal resistance Rint depends on the battery state (e.g., temperature, SOC, SOH (State Of Health), etc.). For example, the higher the temperature, the lower the internal resistance Rint. On the other hand, the external resistance Rext is basically independent of the battery state.

Further, the variance between the internal resistances Rint1-Rintn of the plurality of cells E1-En included in the battery pack 41 tends to be small at the beginning of use and to expand toward the end of use. Usually, a plurality of cells of the same type are used in the battery pack 41 so that the internal resistance Rint at the beginning of use is uniform if there is no problem with the manufacturing quality. On the other hand, the degradation rate of the cell varies due to the influence of the position of the cell in the battery pack 41, environmental conditions, usage method, individual differences, and the like so that the closer to the end of use, the greater the variance of the internal resistance Rint.

On the other hand, the variance between the external resistances Rext1-Rextn of the plurality of cells E1-En included in the battery pack 41 can be regarded as being almost constant regardless of the length of use. The external resistance Rext is determined by mechanical parameters at the time of manufacturing, and the influence of degradation of mechanical parts (busbars, etc.) is small compared to the influence of cell degradation and is negligible unless there is a disconnection or a contact failure.

FIG. 6 is a diagram illustrating a specific example of breakdown of ohmic resistance components of the plurality of cells E1-En contained in the battery pack 41 at the beginning of use. FIG. 5 shows an example in which the external resistance Rext1 of the cell E1 is higher than the external resistances Rext2-Rextn of the other cells E2-En. This suggests that the wiring resistance or contact resistance of the cell E1 may be higher than that of the other cells E2-En. Since the battery is at the beginning of use, the internal resistances Rint1-Rintn of the plurality of cells E1-En are uniform.

The ohmic resistance estimation unit 112 calculates the following expression (1) to estimate respective ohmic resistance Ro1-Ron of the plurality of cells E1-En of the battery pack 41.

$$Roi ( t ) = \vert Δ Vi ( t ) / Δ I ( t ) \vert \qquad ( 1 )$$

where i is a variable between 1 and n.

ΔVi(t) denotes a difference voltage between the voltage measured at a sampling time point (t) and the voltage measured at a sampling time point (t−1), and ΔI(t) denotes a difference current between the current measured at the sampling time point (t) and the current measured at the sampling time point (t−1). Since the accuracy of estimation of the ohmic resistance Roi is higher when it is calculated based on a short-term voltage change and current change, it is desirable to obtain the difference voltage ΔVi and the differential current ΔI between adjacent sampling points. The difference voltage ΔVi and the differential current ΔI between sampling points that are isolated by two or more intervals may be used.

The ohmic resistance Roi cannot be calculated from the battery data in an interval in which the current I is not flowing. The ohmic resistance estimation unit 112 estimates the ohmic Ro1(t)-Ron(t) of the plurality of cells E1-En at the respective sampling time points (t) in the charging and discharging interval, based on, of the battery data for the plurality of cells E1-En included in the battery pack 41 in the predetermined period of acquisition (for example, one month), the voltage data and current data in the charging and discharging interval.

The statistical calculation unit 113 statistically processes, for each sampling time point (t), the ohmic resistances Ro1(t)-Ron(t) of the plurality of cells E1-En included in the particular battery pack 41, and calculates, for each sampling time point (t), a representative value Ro_rep(t) of the ohmic resistance Ro of the single cell of the particular battery pack 41. For example, a median or an average of the ohmic resistances Ro1(t)-Ron(t) of the plurality of cells E1-En can be used as the representative value Ro_rep(t) of the ohmic resistance of the single cell at each sampling time point (t). Hereinafter, an example using a median is assumed.

The correction value generation unit 114 generates external resistance correction values Rextc1(t)-Rextcn(t) for correcting the deviation of the external resistances Rext1(t)-Rextn (t) of the cells E1-En based on differences between the ohmic resistances Ro1(t)-Ron(t) of the cells E1-En included in the particular battery pack 41 and the representative value Ro_rep of the ohmic resistance Ro of the single cell.

The statistical calculation unit 113 statistically processes the external resistance correction values Rextc1(t)-Rextcn(t) of the cells E1-En at a plurality of sampling time points (t), and calculates representative values Rextc1_rep-Rextcn_rep of the external resistance correction values Rextc1-Rextcn of the cells E1-En. For example, a median or an average of the external resistance correction values Rextc1-Rextcn of the cells E1-En can be used as the representative values Rextc1_rep-Rextcn_rep of the external resistance correction values Rextc1-Rextcn of the cells E1-En.

The statistical calculation unit 113 may configure the representative value Rextc_rep of the external resistance correction value Rextc of a cell, for which the absolute value of the representative value Rextc_rep of the external resistance correction value Rextc is equal to or less than a predetermined value, to be 0. The predetermined value can be set by the designer in consideration of the calculation cost of the battery state analysis system 1 and the like.

The statistical calculation unit 113 stores the calculated external resistance correction values Rextc1-Rextcn of the cells E1-En in the resistance correction value retaining unit 121 as registered external resistance correction values Rextc1_rep-Rextcn_rep of the cells E1-En.

The registered external resistance correction values Rextc1_rep-Rextcn_rep of the cells E1-En stored in the resistance correction value retaining unit 121 can be used for correction of the cell voltage as given below by the expression (2).

$$Vic = Vi - I \times Rextci\_rep \qquad ( 2 )$$

where Vic denotes a corrected measured voltage of the cell Ei, Vi denotes a pre-correction measured voltage of the cell Ei, I denotes a measured current of the cell Ei, and Rextci_rep denotes a registered external resistance correction value of the cell Ei.

FIGS. 7A-7B are diagrams illustrating specific examples of the voltage waveform at the time of CC-CV charging of three cells E1-E3 connected in series. Referring to FIG. 7A, the measured voltage V3 of the cell E3 is higher than the measured voltages V1, V2 of the other cells E1, E2. This suggests that the external resistance Rext3 of the cell E3 is higher than the external resistances Rext1 and Rext2 of the other cells E1, E2.

FIG. 7B shows the measured voltage Vc3 that results from correcting the measured voltage V3 of the cell E3 according to the above expression (2). As a result, a waveform close to the measured voltage inherent to the cell E3 can be obtained.

Further, the registered external resistance correction values Rextc1_rep-Rextcn_rep of the cells E1-En stored in the resistance correction value retaining unit 121 can also be used for correction of the internal resistance as given below by the expression (3).

$$Roci = ( \vert Δ Vi / Δ I \vert ) - Rextci\_rep \qquad ( 3 )$$

where Roci denotes a corrected estimate internal resistance value of the cell Ei, ΔVi denotes a change in the measured voltage of the cell Ei, ΔI denotes a change in the measured current of the cell Ei, and Rextci_rep denotes the registered external resistance correction value of the cell Ei.

The registered external resistance correction value Rextci_rep of each cell E1-En of the particular battery pack 41 may be communicated to the electric-powered vehicle 3 equipped with the particular battery pack 41 or to the operation management terminal apparatus 2 managing the electric-powered vehicle 3.

FIG. 8 is a diagram showing an exemplary transition of the estimate internal resistance value of ten cells E1-E10 connected in series. In the example shown in FIG. 8, the estimate internal resistance value ΔV10/ΔI of the cell E10 is about 5 mΩ higher than the estimate internal resistance value of the other cells E1-E9. A similar tendency can be seen at all sampling points. This may be due to the fact that the contact resistance of the busbar of the cell E10 is high or the like. The estimate internal resistance value |ΔV10/ΔI| of the cell E10 can be corrected by subtracting the registered external resistance correction value Rextc10_rep of the cell E10 from the estimate internal resistance value |ΔV10/ΔI| of the cell 10.

FIG. 9 is a flowchart showing the flow of an external resistance correction value generation process performed by the battery state analysis system 1 according to the embodiment. The data acquisition unit 111 acquires, from the data server 6, battery data for each cell E1-En for one month from the start of use of a particular battery pack 41 mounted on the electric-powered vehicle 3 (S10). The ohmic resistance estimation unit 112 calculates the ohmic resistance Roi(t)(=|ΔVi(t)/ΔI(t)| of each cell E1-En at each sampling time point (t), based on the voltage data and current data included in the battery data for each cell E1-En of the battery pack 41 (S11).

The statistical calculation unit 113 statistically processes the ohmic resistances Ro1(t)-Ron(t) of the cells E1-En at each sampling time point (t), and calculates the representative value Ro_rep(t) of the ohmic resistance Ro of the single cell of the particular battery pack 41 (S12).

The correction value generation unit 114 subtracts the representative value Ro_rep (t) of the ohmic resistance Ro of the single cell from the ohmic resistance Roi (t) of each cell E1-En at each sampling time point (t) to generate an external resistance correction value Rextci (t) of each cell E1-En at each sampling time point (t) (S13).

The statistical calculation unit 113 statistically processes the external resistance correction value Rextci (t) of each cell E1-En at a plurality of sampling time points (t), and calculates the representative value Rextci_rep of the external resistance correction value Rextci of each cell E1-En (S14). The statistical calculation unit 113 stores the representative value Rextci_rep of the external resistance correction value Rextci of each cell E1-En thus calculated in the resistance correction value retaining unit 121 as a registered value (S15).

In the above description, an example of calculating the registered external resistance correction values Rextc1_rep-Rextcn_rep of the cells E1-En of the particular battery pack 41 based on the voltage data and current data for one particular battery pack 41 in a predetermined period has been described.

In this regard, based on the voltage data and current data for a plurality of battery packs of the same type in a predetermined period, the registered external resistance correction values Rextc1_rep-Rextcn_rep of the cells E1-En of the battery packs 41 of that type may be calculated. In the battery packs 41 of the same type, a similar deviation of external resistance is likely to occur, for design and manufacturing reasons, in cells at the same position (in particular, the end positions) in the plurality of cells E1-En connected in series.

As described above, according to this embodiment, contribution is made to highly accurate estimation of an internal state of a cell or a parallel cell block by regarding the variance of ohmic resistance of a plurality of cells or parallel cell blocks connected in series as the variance of external resistance of the cell or the parallel cell block, and generating an external resistance correction value.

In this embodiment, it is assumed that the external resistance is hardly changed by environmental conditions (temperature, etc.) or the number of years that have elapsed, and the external resistance correction value is calculated once initially. The season of time of year for calculation does not matter. Therefore, the external resistance correction value of each cell or each parallel cell block can be easily generated.

In the related art, the influence of external factors was not taken into account when estimating the internal resistance of a cell or a parallel cell block. In this embodiment, on the other hand, the internal state of a cell or a parallel cell block can be estimated with high accuracy by considering the influence of external factors of the cell or the parallel cell block.

In this embodiment, a very simple calculation method can be used isolate resistance that is not affected by temperature (external resistance) from resistance that is affected by temperature (internal resistance). Specifically, it is not necessary to perform calculations with high computational costs such as iterative least squares technique, least squares technique, and Kalman filter in order to identify a parameter of the internal resistance. Therefore, an increase in computational resources can be suppressed even when a large amount of data is handled on a cloud server or the like.

In further accordance with this embodiment, an external resistance correction value of each cell or each parallel cell block of the battery packs of the same type can be generated. In that case, the external resistance correction value can be used for each cell or each parallel cell block of the battery packs of that type, thereby reducing the variance of external resistance correction value and computational resources. Even if a sensor abnormality or a degraded cell is mixed in a particular battery pack, an external resistance correction value in which the influence is reduced can be generated.

Given above is a description of the present disclosure based on the embodiment. The embodiment is intended to be illustrative only and it will be understood by those skilled in the art that various modifications to combinations of constituting elements and processes are possible and that such modifications are also within the scope of the present disclosure.

In the above embodiment, an example of generating an external resistance correction value of a cell or a parallel cell block in the battery pack 41 mounted on the electric-powered vehicle 3 using the battery state analysis system 1 connected to the network 5 has been described. In this regard, the battery state analysis system 1 may be incorporated in the battery control unit 46. Further, the battery state analysis system 1 may be incorporated in the charger 4 or the charger adapter 8.

Further, the battery state analysis system 1 according to the present disclosure is not limited to generation of an external resistance correction value of a cell or a parallel cell block in the battery pack 41 mounted on the electric-powered vehicle 3. For example, the system can also be applied to generation of an external resistance correction value of a cell or a parallel cell block in battery packs mounted on electric ships, multicopters (drones), electric motorcycles, electric bicycles, stationary electricity storage systems, smartphones, tablets, notebook PCs, and the like.

The embodiment may be defined by the following items.

### Item 1

A battery state analysis system (1) including:
a data acquisition unit (111) that acquires voltage data and current data for each cell (E1-En) of a battery pack (41) in which a plurality of cells (E1-En) are connected in series or for each parallel cell block of battery pack (41) in which parallel cell blocks, each comprised of a plurality of cells (E1-En) connected in parallel, are connected in series;
an ohmic resistance estimation unit (112) that estimates an ohmic resistance value of each cell (E1-En) or each parallel cell block, based on the voltage data and the current data for each cell (E1-En) or each parallel cell block;
a statistical calculation unit (113) that statistically processes the ohmic resistance value of each cell (E1-En) or each parallel cell block and calculates a representative value of the ohmic resistance value of a single cell (Ei) or a single parallel cell block of a particular battery pack (41) or of a plurality of battery packs of the same type; and
a correction value generation unit (114) that generates an external resistance correction value for correcting deviation of an external resistance of each cell (E1-En) or each parallel cell block, based on a difference between the ohmic resistance value of each cell (E1-En) or each parallel cell block and the representative value of the ohmic resistance value.

Accordingly, it is possible to contribute to highly accurate estimation of an internal state of each cell (E1-En) or each parallel cell block.

### Item 2

The battery state analysis system (1) according to Item 1,
wherein the data acquisition unit (111) acquires voltage data and current data for each cell (E1-En) or each parallel cell block of the battery pack (41) in a predetermined period from a start of use.

Accordingly, it is possible to generate a highly accurate external resistance correction value by using battery data in a period during which the internal resistance is uniform.

### Item 3

The battery state analysis system (1) according to Item 2,
wherein the statistical calculation unit (113) calculates a median or an average of the ohmic resistance value of all cells (E1-En) or all parallel cell blocks of the particular battery pack (41) or the plurality of battery packs (41) of the same type, and
wherein the correction value generation unit (114) generates an external correction resistance value of each cell (E1-En) or each parallel cell block, based on a difference between the ohmic resistance value of each cell (E1-En) or each parallel cell block and the median or the average of the ohmic resistance value.

Accordingly, it is possible to generate an external resistance correction value of each cell (E1-En) or each parallel cell block with high accuracy.

### Item 4

The battery state analysis system (1) according to Item 3,
wherein the statistical calculation unit (113):
calculates a median or an average of the ohmic resistance value of all cells (E1-En) or all parallel cell blocks at each sampling time point in the predetermined period; and
calculates, as a registered value, a representative value of a plurality of external resistance correction values of the cells (E1-En) or the parallel cell blocks generated by the correction value generation unit (114) at a plurality of sampling time points in the predetermined period.

Accordingly, it is possible to generate an external resistance correction value of each cell (E1-En) or each parallel cell block with high accuracy.

### Item 5

The battery state analysis system (1) according to Item 4,
wherein the statistical calculation unit (113) configures the representative value of the external resistance correction value of a cell (Ei) or a parallel cell block, for which an absolute value of the representative value of the external resistance correction value is equal to or less than a predetermined value, to be 0.

Accordingly, it is possible to reduce the volume of computations for estimating an internal state of a cell (Ei) or a parallel cell block.

### Item 6

A battery state analysis method including:
acquiring voltage data and current data for each cell (E1-En) of a battery pack (41) in which a plurality of cells (E1-En) are connected in series or for each parallel cell block of battery pack (41) in which parallel cell blocks, each comprised of a plurality of cells (E1-En) connected in parallel, are connected in series;
estimating an ohmic resistance value of each cell (E1-En) or each parallel cell block, based on the voltage data and the current data for each cell (E1-En) or each parallel cell block;
statistically processing the ohmic resistance value of each cell (E1-En) or each parallel cell block and calculates a representative value of the ohmic resistance value of a single cell (Ei) or a single parallel cell block of a particular battery pack (41) or of a plurality of battery packs of the same type; and
generating an external resistance correction value for correcting deviation of an external resistance of each cell (E1-En) or each parallel cell block, based on a difference between the ohmic resistance value of each cell (E1-En) or each parallel cell block and the representative value of the ohmic resistance value.

Accordingly, it is possible to contribute to highly accurate estimation of an internal state of each cell (E1-En) or each parallel cell block.

### Item 7

A battery state analysis program including:
a module that acquires voltage data and current data for each cell (E1-En) of a battery pack (41) in which a plurality of cells (E1-En) are connected in series or for each parallel cell block of battery pack (41) in which parallel cell blocks, each comprised of a plurality of cells (E1-En) connected in parallel, are connected in series;
a module that estimates an ohmic resistance value of each cell (E1-En) or each parallel cell block, based on the voltage data and the current data for each cell (E1-En) or each parallel cell block;
a module that statistically processes the ohmic resistance value of each cell (E1-En) or each parallel cell block and calculates a representative value of the ohmic resistance value of a single cell (Ei) or a single parallel cell block of a particular battery pack (41) or of a plurality of battery packs of the same type; and
a module that generates an external resistance correction value for correcting deviation of an external resistance of each cell (E1-En) or each parallel cell block, based on a difference between the ohmic resistance value of each cell (E1-En) or each parallel cell block and the representative value of the ohmic resistance value.

Accordingly, it is possible to contribute to highly accurate estimation of an internal state of each cell (E1-En) or each parallel cell block.

1. A battery state analysis system comprising:
a data acquisition unit that acquires voltage data and current data for each cell of a battery pack in which a plurality of cells are connected in series or for each parallel cell block of battery pack in which parallel cell blocks, each comprised of a plurality of cells connected in parallel, are connected in series;
an ohmic resistance estimation unit that estimates an ohmic resistance value of each cell or each parallel cell block, based on the voltage data and the current data for each cell or each parallel cell block;
a statistical calculation unit that statistically processes the ohmic resistance value of each cell or each parallel cell block and calculates a representative value of the ohmic resistance value of a single cell or a single parallel cell block of a particular battery pack or of a plurality of battery packs of the same type; and
a correction value generation unit that generates an external resistance correction value for correcting deviation of an external resistance of each cell or each parallel cell block, based on a difference between the ohmic resistance value of each cell or each parallel cell block and the representative value of the ohmic resistance value.

2. The battery state analysis system according to claim 1,
wherein the data acquisition unit acquires voltage data and current data for each cell or each parallel cell block of the battery pack in a predetermined period from a start of use.

3. The battery state analysis system according to claim 2,
wherein the statistical calculation unit calculates a median or an average of the ohmic resistance value of all cells or all parallel cell blocks of the particular battery pack or the plurality of battery packs of the same type, and
wherein the correction value generation unit generates an external correction resistance value of each cell or each parallel cell block, based on a difference between the ohmic resistance value of each cell or each parallel cell block and the median or the average of the ohmic resistance value.

4. The battery state analysis system according to claim 3,
wherein the statistical calculation unit:
calculates a median or an average of the ohmic resistance value of all cells or all parallel cell blocks at each sampling time point in the predetermined period; and
calculates, as a registered value, a representative value of a plurality of external resistance correction values of the cells or the parallel cell blocks generated by the correction value generation unit at a plurality of sampling time points in the predetermined period.

5. The battery state analysis system according to claim 4,
wherein the statistical calculation unit configures the representative value of the external resistance correction value of a cell or a parallel cell block, for which an absolute value of the representative value of the external resistance correction value is equal to or less than a predetermined value, to be 0.

6. A battery state analysis method comprising:
acquiring voltage data and current data for each cell of a battery pack in which a plurality of cells are connected in series or for each parallel cell block of battery pack in which parallel cell blocks, each comprised of a plurality of cells connected in parallel, are connected in series;
estimating an ohmic resistance value of each cell or each parallel cell block, based on the voltage data and the current data for each cell or each parallel cell block;
statistically processing the ohmic resistance value of each cell or each parallel cell block and calculates a representative value of the ohmic resistance value of a single cell or a single parallel cell block of a particular battery pack or of a plurality of battery packs of the same type; and
generating an external resistance correction value for correcting deviation of an external resistance of each cell or each parallel cell block, based on a difference between the ohmic resistance value of each cell or each parallel cell block and the representative value of the ohmic resistance value.

7. A non-transitory computer-readable recording medium having embodied thereon a battery state analysis program comprising:
a module that acquires voltage data and current data for each cell of a battery pack in which a plurality of cells are connected in series or for each parallel cell block of battery pack in which parallel cell blocks, each comprised of a plurality of cells connected in parallel, are connected in series;
a module that estimates an ohmic resistance value of each cell or each parallel cell block, based on the voltage data and the current data for each cell or each parallel cell block;
a module that statistically processes the ohmic resistance value of each cell or each parallel cell block and calculates a representative value of the ohmic resistance value of a single cell or a single parallel cell block of a particular battery pack or of a plurality of battery packs of the same type; and
a module that generates an external resistance correction value for correcting deviation of an external resistance of each cell or each parallel cell block, based on a difference between the ohmic resistance value of each cell or each parallel cell block and the representative value of the ohmic resistance value.
